(19) United States
(12) Patent Application Publication
(10) Pub. No.: US 2004/0001316 A1
(43) Pub. Date: Jan. 1, 2004

(54) Cooling unit for cooling heat generating component and electronic apparatus having the cooling unit

(75) Inventors: Yoshinori Kamikawa, Tokyo (JP); Satoshi Ooka, Tokyo (JP)

Correspondence Address: FOLEY & LARDNER, 2029 CENTURY PARK EAST, SUITE 3500, LOS ANGELES, CA, 90067

(73) Assignee: KABUSHIKI KAISHA TOSHIBA

(21) Appl. No.: 10/366,766

(22) Filed: Feb. 14, 2003

(30) Foreign Application Priority Data
Jun. 28, 2002 (JP) JP2002-190893

(51) Int. Cl. H05K 7/20

(52) U.S. Cl. 361/700; 361/699

(57) ABSTRACT

An electronic apparatus has a housing, a heat generating component arranged in the housing, a heat pipe including a flat heat receiving surface integrally formed at one end, a deformable thermal conductive material, and a heat radiation member. The deformable thermal conductive material is arranged between the flat heat receiving surface and the heat generating component, and thermally connects the flat heat receiving surface and the heat generating component. The heat radiation member is thermally connected to the other end of the heat pipe.

### CROSS-REFERENCE TO RELATED APPLICATIONS

This application is based upon and claims the benefit of priority from-Japanese Patent Application No. 2002-190893, filed Jun. 28, 2002, the entire contents of which are incorporated herein by reference.

### BACKGROUND OF THE INVENTION

1. Field of the Invention

This invention relates to a cooling unit for facilitating the radiation of heat generating component such as a semiconductor package including a Central Processing Unit (hereinafter “CPU”) or a memory module, and also an electronic apparatus, such as a portable computer, which incorporates the cooling unit.

2. Description of the Related Art

CPUs for use in electronic apparatuses such as portable computers have come to generate an increased amount of heat due to increased processing speed and multiple functions. Conventional electronic apparatus is therefore equipped with a cooling unit of the air-cooling type that forcibly cools a CPU. The cooling unit has a heat receiving portion, a heat-exchanging portion, a heat pipe, and an electric fan. The heat-receiving portion has a plate whose size matches the CPU. This plate is thermally connected to the CPU. The heat-exchanging portion has a plurality of heat radiation fins and is set at a position distant from the CPU. The heat pipe provides a bridge between the heat receiving portion and the heat-exchanging portion. The heat pipe has an end corresponding to the heat-receiving portion. This end is thermally connected to the plate of the heat-receiving portion by means of a separate, intermediate plate and may be also include soldering, grease, thermal conductive sheet, or the like. The electric fan feeds cooling air to the heat-exchanging portion. U.S. Pat. Nos. 6,125,035, 6,137,683, 6,166,906, and 6,233,146 disclose the above types of cooling structure.

When the CPU generates heat, the heat from the CPU is transferred to the plate of the heat-receiving portion. The heat thus transferred to the plate is further transferred to the heat-exchanging portion through the heat pipe. Then, the heat is discharged to the outside of the electronic apparatus by thermal exchange with the cooling air.

In a conventional apparatus, a plate of a heat-receiving portion is inserted between the CPU that generates heat and the end of the heat pipe that receives this heat. Therefore, the heat transfer path from the CPU to the end of the heat pipe is so long as to hinder efficient thermal conduction.

Further, the portion that connects the end of the heat pipe and the plate of the heat-receiving portion to each other has a large thermal resistance. As a result, a limit is set on the amount of heat that may be transferred from the CPU to the heat pipe.

In the near future, CPUs for use in electronic apparatuses will have much higher performance. It is hence predicted that the amount of heat generated from each CPU will increase remarkably. The conventional structure in which less heat from the CPU is transferred to the heat pipe may therefore be insufficient for attaining sufficient cooling is performance for the CPU.

### BRIEF SUMMARY OF THE INVENTION

Embodiments of the present invention provide a cooling unit which radiates heat generated by a heat generating component of an electronic device.

According to embodiments of the present invention, a cooling unit for cooling a heat generating component is described. According to one embodiment, a heat pipe includes a flat heat-receiving surface formed at one end. A deformable thermal conductive material is arranged between the flat heat receiving surface and a heat generating component, and is thermally connected to the flat receiving surface and the heat generating component. A heat radiation member is thermally connected to the other end of the heat pipe.

Additional features and advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing a portable computer according to a first embodiment of the present invention;

FIG. 2 is a perspective view showing a positional relationship between the housing and cooling unit in the first embodiment;

FIG. 3 is a perspective view showing a positional relationship among the CPU, heat pipe, heat-exchanging portion, and electric fan in the first embodiment;

FIG. 4A is a side view showing: the heat-receiving portion of the heat pipe according to the first embodiment;

FIG. 4B is a front view showing the heat-receiving portion of the heat pipe according to the first embodiment;

FIG. 5A is a cross-sectional view showing the heat-receiving portion of the heat pipe according to the first embodiment;

FIG. 5B is a cross-sectional view cut along the line X-X shown in FIG. 5A;

FIG. 6 is a side view showing a state in which the heat-receiving portion of the heat pipe is thermally connected to the CPU through the spring member, according to the first embodiment;

FIG. 7A is a side view showing the heat-receiving portion of the heat pipe according to a second embodiment of the present invention;

FIG. 7B is a front view showing the heat-receiving portion of the heat pipe according to the second embodiment of the present invention;

FIG. 8A is a cross-sectional view showing the heat receiving portion of the heat pipe according to the second embodiment; and

FIG. 8B is a cross-sectional view cut along the line Y-Y shown in FIG. 8A.

### DETAILED DESCRIPTION

Preferred embodiments according to the present invention will be described hereinafter with reference to the accompanying drawings.

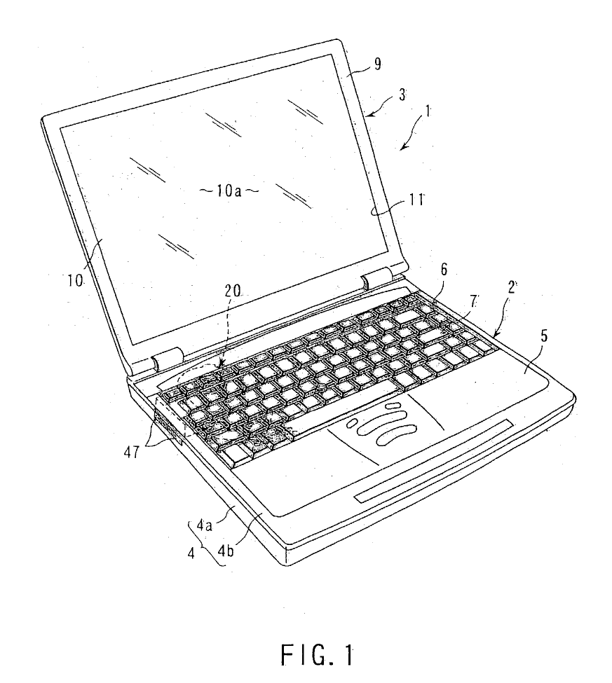

FIG. 1 shows a portable computer 1 as an electronic apparatus. The portable computer 1 comprises a computer main body 2 and a display unit 3 supported by the main body 2.

The main body 2 has a flat box-like housing 4. The housing 4 is constituted by a base 4a and an upper cover 4b. The upper cover 4b has a palm rest 5 and a keyboard installation part 6. The palm rest 5 extends in the widthwise direction of the housing 4 in the front half part of the housing 4. The keyboard installation part 6 is positioned at the rear of the palm rest 5. A keyboard 7 is attached to the keyboard installation part 6.

The display unit 3 includes a display housing 9, and a liquid crystal display panel 10 contained in the display housing 9. The liquid crystal display panel 10 has a display screen 10a. The display screen 10a is exposed to the outside of the display housing 9 through an opening part 11 formed in the front surface of the display housing 9. The display housing 9 is coupled to the housing 4 by a hinge (not shown) at a rear end part of the housing such that it may pivot between a closed position in which the display unit 3 is folded onto the palm rest 5 and keyboard 7, and an open position in which the palm rest 5, the keyboard 7, and the display screen 10a are exposed.

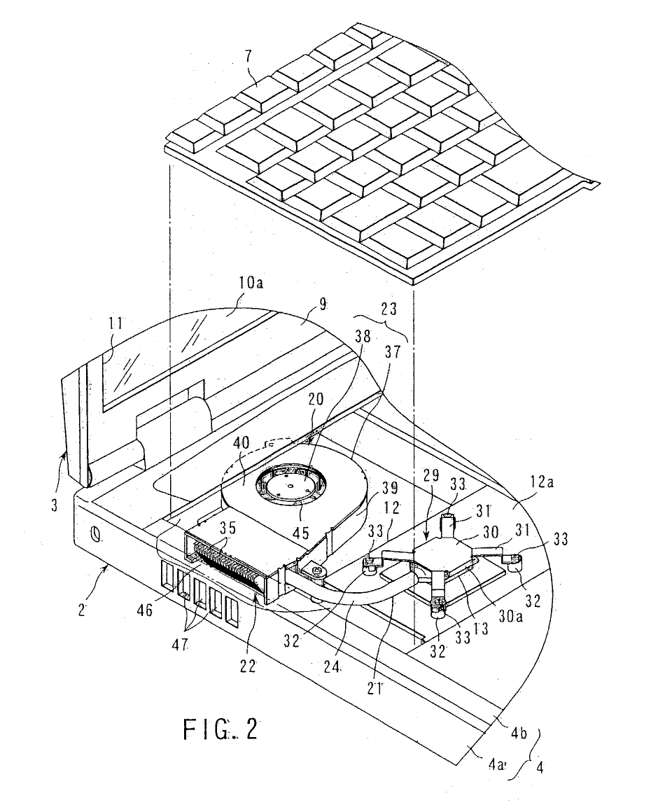

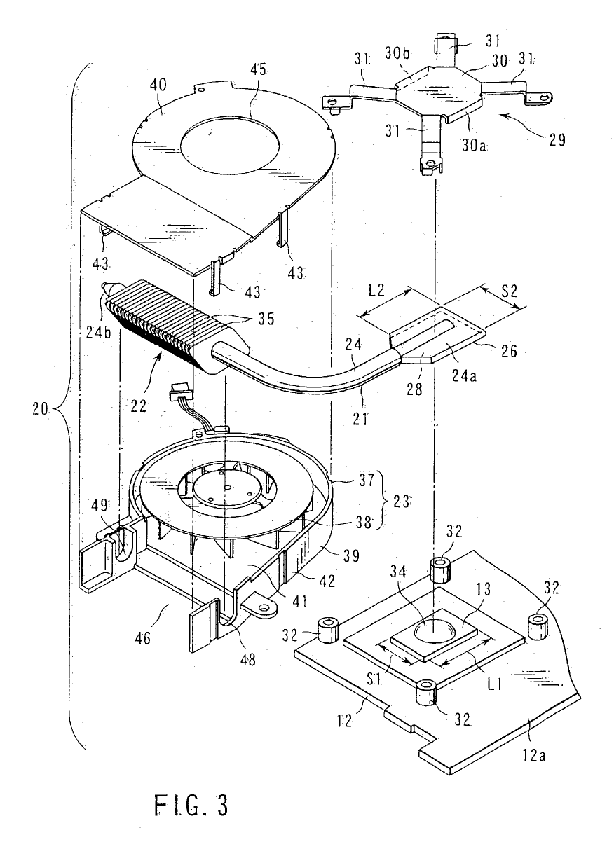

As shown in FIGS. 2, and 3, the housing 4 contains a printed circuit board 12 and a cooling unit 20. The printed circuit board 12 has an upper surface 12a that faces the keyboard installation part 6. A CPU 13 as a heat-generating component is soldered to the upper surface 12a of the printed circuit board 12. The CPU 13 is a rectangular circuit component that has long sides L1 and short sides S1 perpendicular to the long sides L1. The top of the CPU 13 is a flat surface. The CPU 13 has a very large heat generation amount during operation. Cooling is required for maintaining stable operation of the CPU 13.

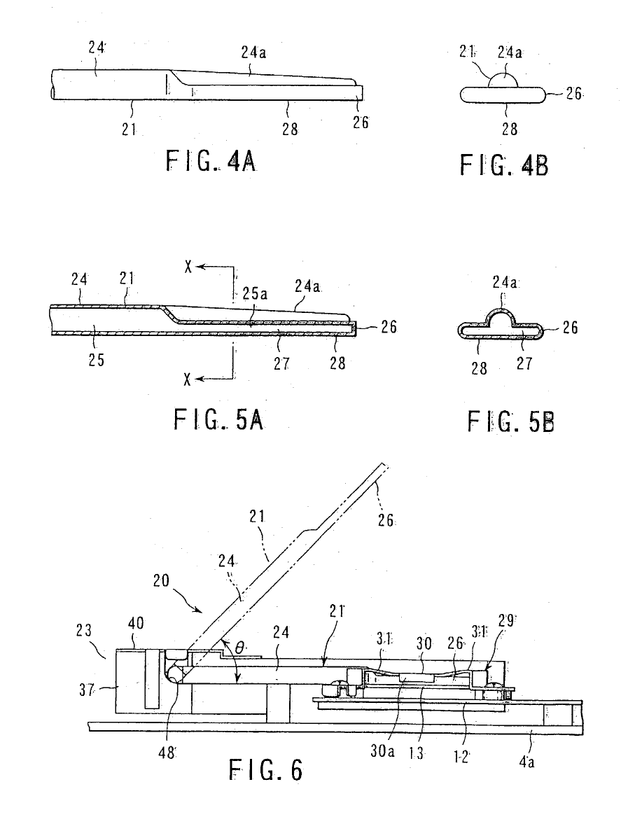

The cooling unit 20 serves to forcibly cool the CPU 13. The cooling unit 20 has a heat pipe 21 that constitutes a heat transferring member, a heat-exchanging portion 22, and an electric fan 23. The heat pipe 21 has a metal outer tube 24 as a main body. The outer tube 24 has ends 24a and 24b. As the heat pipe 21 is made of same material, i.e. copper, from the one end 24a to the other end 24b, the thermal conductivity of the heat pipe is constant in entire portion. The outer tube 24 is bent at right angle. As shown in FIGS. 4A, 4B, 5A and 5B, the outer tube 24 has a cooling medium path 25 that encloses a cooling medium, i.e. water. The cooling medium path 25 is formed between, the end 24a and 24b throughout the outer tube 24.

A heat-receiving portion 26 is formed at the end 24a of the outer tube 24. The heat-receiving portion 26 is formed by pressing the end 24a of the outer tube 24 to be flattened. The inside of the heat-receiving portion 26 forms a hollow heat-receiving chamber 27. The heat-receiving chamber 27 is positioned at a heat receiving end 25a of the cooing medium path 25.

The heat-receiving chamber 27 has a flat heat-receiving surface 28. The heat-receiving surface 28 is connected thermally to the heat-receiving chamber 27 and is positioned on the underside of the heat-receiving portion 26. Meanwhile, a part of the outer tube 24 remains in the form of an semicircular convex part on the topside of the heat-receiving portion 26. The volume of the heat-receiving chamber 27 is therefore increased by an amount equivalent to the convex part, so that thermal conduction to the cooling medium may be made efficiently.

As shown in FIG. 3, the heat-receiving surface 28 has a rectangular shape having long sides L2 and short sides S2 perpendicular to the long sides L2. The long sides L2 of the heat-receiving surface 28 extend along the axial direction of the end 24a of the outer tube 24. Each long side L2 of the heat-receiving surface 28 has a length preferably equal to that of each long side L1 of the flat surface of the CPU 13. Likewise, each short side S2 of the heat-receiving surface 28 has a length preferably equal to that of each short side S1 of the flat surface of the CPU 13. Alternatively, the, heat-receiving surface 20 could be larger (or less preferably smaller), than the flat surface of the CPU 13. The heat-receiving surface 28 of the heat pipe 21 is overlapped on the CPU 13 through thermal conductive grease 34. The thermal conductive grease 34 includes high thermal conductive particles, and therefore has a high thermal conductivity. The grease 34 is easily deformed so as to absorb variation in thickness between the flat heat receiving surface 28 and the flat surface of the CPU 13, and is thermally connected to the heat-receiving surface 28 and the flat surface of the CPU 13.

The heat-receiving portion 26 is pressed against the flat surface of the CPU 13 by a spring member 29. The spring member 29 has a press plate 30 and four leg portions 31. The press plate 30 has a rectangular shape whose size corresponds to the size of the heat-receiving portion 26. The press plate 30 has a pair of engagement pieces 30a and 30b. The engagement pieces 30a and 30b are bent downwards from edge portions of the press plate 30, and face each other. As the clearance between the engagement pieces 30a and 30b may be close to each short side S1, and S2, the engagement pieces 30a and 30b may clamp the CPU 13 and the heat receiving portion 26, positioning the CPU 13, the heat receiving portion 26, and the press plate 30 relatively to each other.

The leg portions 31 of the spring member 29 extend radially from the four corner portions of the press plate. Tip ends of the leg portions 31 are fixed respectively to four boss portions 32 on the printed circuit board 12 by screws 33. The leg portions 31 energize elastically the press plate 30 toward the heat-receiving portion 26 of the heat pipe 21. As a result, the heat-receiving surface 28 of the heat-receiving portion 26 is pressed against the CPU 13, thus thermally connecting the heat receiving surface 28 and the CPU 13 to each other through the grease 34.

The heat-exchanging portion 22 of the cooling unit 20 has a large number of heat radiation fins 35. The heat radiation fins 35 are disposed in line at a predetermined interval. The end 24b of the outer tube 24 of the heat pipe 21 penetrates the center parts of the heat radiation fins 35, and are connected thermally to the fines 35.

As shown in FIGS. 2 and 3, the electric fan 23 includes a fan case 37 and an impeller 38 contained in the fan case 37. The fan case 37 is constituted of two pieces, namely a case body 39 and a cover 40. The case body 39 has a bottom wall 41 and a side wail 42 standing on the circumferential edge of the bottom wall 41. The cover 40 covers over the upper edge of the side wall 42. The cover 40 has a plurality of nails 43 extending downwards along the side wall 42. The tips of the nails 43 hook to the circumferential part of the bottom wall 41, connecting the cover 40 to the case body 39.

The fan case 37 has an inlet port 45 and an outlet port 46. The inlet port 45 is open in the center part of the cover 40 and faces the part of the rotation center of the impeller 38. The outlet port 46 is open in the side wall 42 of the case body 39 and faces the outer circumferential part of the impeller 38. Further, the outlet port 46 faces ventilation holes 47 open in the side surface of the housing 4.

The heat-exchanging portion 22 is positioned corresponding to the outlet port 46 of the fan case 37. The side wall 42 of the fan case 37 has a penetration slit 48 and a receiving groove 49. The end 24b of the outer tube 24 of the heat pipe 21 penetrates through the penetration slit 48. The tip end of the end 24b is supported rotatably in the receiving groove 49.

The heat pipe 21 may therefore rotate between first and second positions about a pivot, i.e., the end 24b. In the first position, the heat-receiving portion 26 of the heat pipe 21 overlaps the CPU 13, as indicated by a continuous line in FIG. 6. In the second position, the heat-receiving portion 26 of the heat pipe 21 comes upwards away from the CPU 13. In other words, the heat pipe 21 is supported by the fan case 37 such that the pipe 21 may be rotated between the first position where the heat-receiving portion 26 overlaps the CPU 13 and the second position where the portion 26 stands away from the CPU 13.

As the heat-receiving portion 26 may be moved to the second position from the first position, it is easier to replace the CPU 13. At this time, the rotational angle θ of the heat pipe 21 may be 20 to 45 degrees, so as to avoid the heat receiving position 26 from obstructing replacement services for the CPU 13.

The impeller 38 of the electric fan 23 rotates when the portable computer 1 is started or when the temperature of the CPU 13 reaches a predetermined value. As this impeller 38 rotates, the air inside the housing 4 is sucked from the inlet port 45 to the center part of the rotation of the impeller 38. This air is discharged from the outer peripheral part of the impeller 38 and blown as cooling air to the heat-exchanging portion 22. The cooling air passes between the heat radiation fins 35 of the heat exchanging portion 22 and is exhausted to the outside of the housing 4.

In the portable computer 1 with a structure as described above, heat from the CPU 13 is transferred to the heat-receiving portion 26 through the grease 34 whenever the CPU 13 generates heat. This thermal conduction to the heat-receiving portion 26 heats and vaporizes the cooling medium in the heat-receiving chamber 27. The vapor of the cooling medium flows to the end 24b of the heat pipe 21 through the cooling medium path 25 from the heat-receiving chamber 27. The heat-exchanging portion 22 connected to the end 24b of the heat pipe 21 is forcibly cooled by the cooling air fed from the electric fan 23. The end 24b of the heat pipe 21 is therefore kept at a lower temperature than the heat-receiving portion 26.

As a result, the vapor guided to the end 24b of the heat pipe 21 radiates heat and condenses there. The heat radiated by the condensation in carried by the flow of the cooling air and is further radiated to the outside of the housing 4 from the ventilation ports 47.

The cooling medium thus condensed to liquid by the heat exchange returns to the heat receiving chamber 27, transferring inside the cooling medium path 25 by capillary action. The cooling medium is then vaporized again receiving the heat from the CPU 13. The vaporization and condensation of the cooling medium are thus repeated to transfer the heat from the CPU 13 to the heat-receiving portion 26 and further to the heat-exchanging portion 22.

In the heat pipe 21 described above, a flat heat receiving portion 26 is integrally formed at the end 24a of the outer tube 24 that encloses the cooling medium. The heat-receiving portion 26 has a flat heat receiving surface 28 wider than the outer tube 24.

The heat-receiving surface 28 is overlapped on the CPU 13 with the grease 34.

Therefore, no special thermal conductive plate is provided between the heat pipe 21 and the CPU 13. The thermal resistance of the part thermally connecting the heat pipe 21 and the CPU 13 is reduced accordingly. As a result, heat from the CPU 13 transfers efficiently to the heat pipe 21. The cooling performance for the CPU 13 is thus improved.

The heat-receiving portion 26 is obtained simply by pressing an end 24a of the outer tube 24 to be flat. The heat-receiving portion 26 may thus be manufactured easily, so the costs may be reduced.

Further, the cooling medium path 25 inside the outer tube 24 has the heat receiving end 25a positioned in the heat-receiving chamber 27. The cooling medium may therefore spread to the very corners of the heat-receiving chamber 27, resulting in an increased amount of heat transferred to the cooling medium from the CPU 13.

In addition, the heat-receiving surface 28 of the heat-receiving portion 26 is overlapped on the CPU 13 through the thermal conductive grease 34, with the long sides L2 of the surface 28 set along the long sides L1 of the CPU 13. The contact area between the heat receiving surface. 28 and the CPU 13 may be securely obtained, so that the rectangular CPU 13 may be cooled efficiently. Heat from the CPU 13 may be absorbed effectively, particularly because each long side L2 of the heat-receiving surface 28 has a length equivalent to each long side L1 of the CPU 13. As a result, the cooling performance for the CPU 13 may be improved much more.

Also, according to the structure as described above, the end 24b of the heat pipe 21 is supported rotatably by the fan case 37. The flat heat-receiving portion 26 is thus movable in a direction in which the portion 26 moves close to or far from the CPU 13. When the CPU 13 is replaced, the spring member 29 which presses the heat receiving portion 26 against the CPU 13 need only to be detached from the printed circuit board 12. Complicated services for disassembling are hence not required and services for replacing the CPU 13 may be carried out simply and rapidly.

Further, the outer tube 24 of the heat pipe 21 is bent such that one end 24a and the other end 24b are kept in a positional relationship of being perpendicular to each other. Therefore, the distance between the heat-receiving portion 26 of the heat pipe 21 and the fan case 37 is shorter, compared with a straight heat pipe. The cooling unit 20 is accordingly compact.

The present invention, however, is not limited to the first embodiment described above.

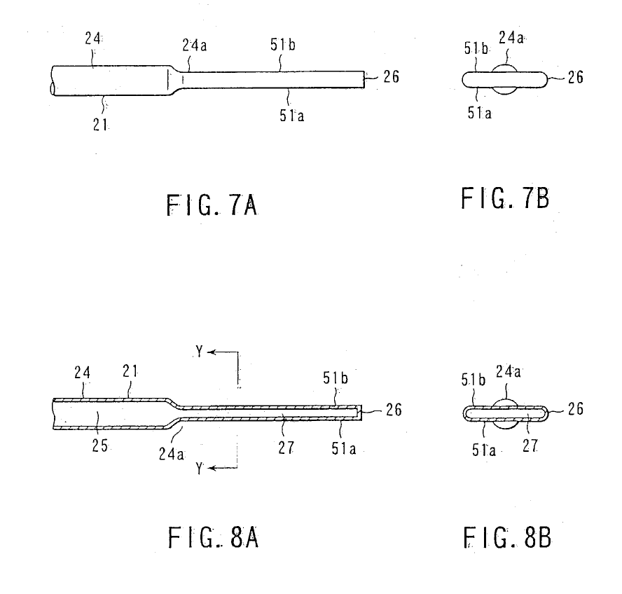

FIGS. 7A, 7B, 8A, and 8B show the second embodiment of the present invention. This second embodiment is different in the shape of the heat-receiving portion 26 of the heat pipe 21 than the first embodiment.

As shown in FIGS. 7A and 8A, the heat-receiving portion 26 has a first heat receiving surface 51a and a second heat receiving surface 51b. The first and second heat receiving surfaces 51a and 51b are provided parallel to each other with a heat-receiving chamber 27 inserted there between. Therefore, the first heat receiving surface 51a is positioned on the down side of the heat-receiving portion 26. The second heat receiving surface 51b is positioned on the top side of the heat-receiving portion 26.

According to this structure, either the first heat receiving surface 51a or the second heat receiving surface 51b may be overlapped on the CPU 13 through the thermal conductive grease 34. A limitation to the orientation of the heat-receiving portion 26 in thermally connecting the heat pipe 21 is overcome accordingly. The CPU 13 and the heat pipe 21 may hence be thermally connected easily to each other.

In the first embodiment, the CPU 13 and the heat-receiving portion 26 of the heat pipe 21 are each rectangular. The CPU 13 and the heat-receiving portion 26 are, however, not limited to rectangular shapes but may have square shapes, for example.

Further, the circuit component which generates heat is not limited to a CPU but may be a chip set, a memory module, or the like.

The thermal conductive material is not limited to grease. A thermal conductive sheet that is elastic rubber member that is formed by, for example, adding alumina to silicone resin, and has a high thermal conductivity, may be used. The size and/or dimensions of the thermal conductive sheet may be selected, so that it may compensate for variations in thickness of the height of the CPU 13. (i.e. roughness of the surface of the CPU 13).

The heat-receiving surface 28 of the heat pipe 21 may be overlapped directly over the CPU 13 (without need for conductive grease or conductive sheet), in the case that the variation in thickness between the surface of the CPU 13 and the surface of the heat-receiving surface 28 is not significant.

The heat-receiving surface 26 is not limited to be flat. The form of the heat-receiving surface 26 may be deformed in conformity with the shape of the heat generating component. When a surface of the heat generating component is formed convexly, the heat receiving surface 26 may be concave so that the contacting area is large.

In addition, electronic apparatuses according to the present invention are not particularly limited to portable computers. The present invention is applicable to various data processing apparatuses each including a circuit component that generates a large amount of heat.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A cooling unit for cooling a heat generating component, comprising:
a heat pipe including a flat heat receiving surface formed at one end;
a deformable thermal conductive material arranged between the flat heat receiving surface and the heat generating component; and
a heat radiation member thermally connected to the other end of the heat pipe.

2. A cooling unit according to claim 1, wherein the deformable thermal conductive material comprises is thermal conductive grease.

3. A cooling unit according to claim 1, wherein the deformable thermal conductive material comprises thermal conductive sheet.

4. A cooling unit according to claim 1, wherein the flat heat receiving surface is formed by deforming the one end of the heat pipe to be flattened.

5. A cooling unit according to claim 4, wherein the heat pipe has an heat receiving chamber formed by both the flat heat receiving surface and a surface extended from the flat heat receiving surface.

6. A cooling unit according to claim 1, further comprising a spring member configured to press the flat heat receiving surface against the heat generating component.

7. A cooling unit according to claim 1, wherein the heat generating component has a flat surface, and a dimension of the flat heat receiving surface is approximately the same as that of the flat surface of the heat generating component.

8. A cooling unit according to claim 1, wherein the flat heat receiving surface is wider than the heat pipe.

9. A cooling unit for cooling a heat generating component having a flat surface, comprising:
a heat pipe including a flat heat receiving surface in thermal contact with the flat surface of the heat generating component, the flat heat receiving surface being integrally formed at one end of the heat pipe and having a dimension approximately the same as that of the flat surface of the heat generating component; and
a heat radiation member thermally connected to the other end of the heat pipe,
wherein heat is transferred from the heat generating component to the heat radiation member through the heat pipe.

10. A cooling unit for cooling a heat generating component having a flat surface, comprising:
a heat pipe including a flat heat receiving surface in thermal contact with the flat surface of the heat generating component, the flat heat receiving surface being integrally formed at one end of the heat pipe and being wider than the heat pipe; and
a heat radiation member thermally connected to the other end of the heat pipe,
wherein heat is transferred from the heat generating component to the heat radiation member through the heat pipe.

11. An electronic apparatus, comprising:
a housing having a heat generating component contained therein;
a heat exchanging portions which is contained in the housing and radiates heat from the heat generating component;
a heat pipe configured to transfer the heat from the heat generating component to the heat exchanging portion, the heat pipe including a tubular body and a flat heat receiving surface formed integrally at an end of the tubular body; and
a deformable thermal conductive material contacting the flat heat receiving surface and the heat generating component.

12. An electronic apparatus according to claim 11, wherein the deformable thermal conductive material comprises thermal conductive grease.

13. An electronic apparatus according to claim 11, wherein the deformable thermal conductive material comprises thermal conductive sheet.

14. An electronic apparatus according to claim 11, wherein the flat heat receiving surface of the heat transferring member is formed by deforming the end of the body.

15. An electronic apparatus according to claim 11, wherein the tubular body has a cooling medium path traversed by the cooling medium, and the cooling medium path extends to the back of the flat heat receiving surface.

16. An electronic apparatus according to claim 11, wherein the heat generating component has a rectangular shape having long sides and short sides, and the flat heat receiving surface has a rectangular shape having long sides and short sides, the long sides of the heat receiving surface each having a length proximately equal to that of each of the long sides of the heat generating component.

17. An electronic apparatus according to claim 11, wherein the flat heat receiving surface is pressed against the heat-generating component through a spring member.

18. An electronic apparatus according to claim 11, wherein the flat heat receiving surface is wider than the tubular body.

19. An electronic apparatus according to claim 11, further comprising a fan which is contained in the housing and feeds cooling air to the heat exchanging portion.

20. An electronic apparatus according to claim 19, wherein the fan has a fan case and an impeller contained in the fan case, and the heat exchanging portion is supported by the fan case.

21. An electronic apparatus according to claim 20, wherein the tubular body has another end supported rotatably by the fan case, and the heat pipe is movable about the other end of the tubular body serving as a pivot, between a first position where the flat heat receiving surface overlaps the heat generating component and a second position where the flat heat generating surface is spaced apart from the heat generating component.

22. An electronic apparatus comprising:
a housing;
a circuit component which is contained in the housing and generates heat, and has long sides and short sides extending in directions intersecting the long sides;
a heat exchanging portion which is contained in the housing and radiates heat from the circuit component; and
a heat transferring member which transfers the heat from the circuit component to the heat exchanging portion and includes a tubular body and a flat heat receiving surface integrally formed at an end of the tubular body, the heat receiving surface having long sides and short sides extending in directions intersecting the long sides, and the flat heat receiving surface being thermally connected to the circuit component such that the long sides of the heat receiving surface are positioned along the long sides of the circuit component.

23. An electronic apparatus according to claim 22, wherein the long sides of the heat receiving surface extend in the axial direction of the tubular body.

24. An electronic apparatus according to claim 22, wherein the flat heat receiving surface is formed by deforming the end of the tubular body.

25. An electronic apparatus according to claim 22, wherein each of the long sides of the heat receiving surface has a length substantially equal to that of each of the long sides of the heat generating component, and each of the short sides of the heat receiving surface has a length substantially equal to that of each of the short sides of the heat generating component.

26. An electronic apparatus, comprising:
a housing;
a heat generating component arranged in the housing, the heat generating component having a flat surface;
a heat pipe including a flat heat receiving surface integrally formed at one end;
a deformable thermal conductive material arranged between the flat heat receiving surface and a heat generating component, and thermally connected therebetween; and
a heat radiation member thermally connected to the other end of the heat pipe.

27. An electronic apparatus according to claim 26, wherein the deformable thermal conductive material comprises thermal conductive grease.

28. An electronic apparatus according to claim 26, wherein the deformable thermal conductive material comprises thermal conductive sheet.
